(19) United States
(12) Patent Application Publication
(10) Pub. No.: US 2009/0091381 A1
(43) Pub. Date: Apr. 9, 2009

(54) GAIN CONTROL DEVICE

(75) Inventor: Shigeru Amano, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI ELECTRIC INDUSTRY CO., LTD., Tokyo (JP)

(21) Appl. No.: 12/236,704

(22) Filed: Sep. 24, 2008

(30) Foreign Application Priority Data
Oct. 5, 2007 (JP) 2007-262149

(51) Int. Cl. H03G 3/20

(52) U.S. Cl. 330/2

(57) ABSTRACT

The present invention aims to suppress degradation of a reception characteristic even in such an environment that the signal strength of an inputted analog signal varies due to a variation in a received electric field. A controller acquires characteristic information showing each gain characteristic indicative of a relationship between the signal strength of the analog signal and the gain corresponding to the analog signal at an amplifier from a CPU. An AGC controller derives gains each corresponding to the signal strength detected at an ADC according to the gain characteristics indicated by the acquired characteristic information, whenever necessary, and outputs the same to the amplifier through a terminal.

### BACKGROUND OF THE INVENTION

The present invention relates to a gain control device.

A receiving section 10′ that receives a digital terrestrial broadcast is divided into, for example, a tuner LSI 12′ connected to an antenna 11′ and an OFDM demodulation LSI 14′ as shown in FIG. 14. Both of them have been provided by many manufactures.

Since the tuner LSI 12′ is fabricated by the respective manufacturers under various manufacturing processes and design concepts, it has various gain characteristics.

Therefore, the OFDM demodulation LSI 14′ needs to perform gain control corresponding to the gain characteristics of amplifiers 19′ provided in the tuner LSI 12′. Thus, the tuner LSI 12′ capable of corresponding thereto is restricted.

When, however, the OFDM demodulation LSI 14′ detects the signal strength of a signal inputted from the tuner LSI 12′ and feeds back the gain to the tuner LSI 12′ through an AGC (Auto Gain Control) controller 30′ as shown in FIG. 14, the gains of the amplifiers 19′ are kept stable and the inputted signal is also settled for the optimum signal strength in a static environment unaffected by fading or the like even though the gain characteristics of the amplifiers 19′ are not incorporated properly.

Thus, as a technique for controlling the gain by feedback, there has been disclosed in a patent document 1 (Japanese Unexamined Patent Publication No. 2002-290178), for example, a technique wherein two amplifiers are provided in series, and the level of a signal outputted from the amplifier of subsequent stage is detected and the gain of the subsequent-stage amplifier is finely controlled by its detected output, thereby promptly handling a small variation in level developed in a relatively short period of time, whereas the detected output and a reference level are compared and the gain of the amplifier of previous stage is controlled corresponding to the result of its comparison, thereby to follow a large level variation changed in a relatively long period of time even though a time delay is developed in control.

Meanwhile in recently increasing mobile applications, the tuner LSI 12′ and the OFDM demodulation LSI 14′ also need to adapt to such a dynamic environment that a received electric field always varies as typified by fading or a multipath.

When, however, the AGC controller 30′ does not suitably adapt to the gain characteristic of the tuner LSI 12′, there is a case in which it cannot follow a variation in the strength of the inputted signal, so that its reception characteristic is degraded greatly.

As a factor of degradation in the reception characteristic, there is known, for example, a dynamic range of an analog-digital converter (hereinafter called “ADC”) 20′. Normally, the ADC 20′ does not have a dynamic range so as to cover the entire signal strength of an inputted signal. The relationship between the signal strength of the inputted signal and the dynamic range is brought to such a relationship as shown in FIG. 15.

When this dynamic range cannot follow a variation due to fading, an out-of-dynamic range is clipped to the end of the dynamic range. Since an OFDM (Orthogonal Frequency Division Multiplexing) modulation system adopted in a digital terrestrial method in particular is of a system in which large degradation in characteristic occurs when such saturation is developed, a fatal condition is reached.

The above-described problem arises so long as the AGC controller 30′ controls the gain of each amplifier 19′ in such a manner that the strength of the inputted signal is within the dynamic range of the ADC 20′.

If in order to perform this follow-up, the OFDM demodulation LSI 14′ can measure the gain characteristic of the tuner LSI 12′ in advance and the AGC controller 30′ can perform gain control corresponding to the gain characteristic, no problem occurs because building into the optimum condition is enabled.

It is however difficult to adapt the gain characteristic of the AGC controller 30′ to the gain characteristics set by plural manufacturers. Adaptation to a new tuner LSI 12′, which is not capable of recognizing a gain characteristic at a design stage is so difficult.

Incidentally, although this has been described as the problem related to communication equipment used in digital terrestrial broadcasting, it is of a problem common to each communication equipment which performs gain feedback control on an external device.

### SUMMARY OF THE INVENTION

The present invention has been made in view of the foregoing facts, and therefore, an object of the present invention is to provide a gain control device capable of suppressing degradation of a reception characteristic even in such an environment that the strength of an analog signal varies due to a variation in a received electric field.

According to a first aspect of the invention, for attaining the above object, there is provided a gain control device comprising an input terminal inputted with an analog signal amplified with predetermined gain by an external amplifier circuit, means for detecting a signal strength of the analog signal inputted to the input terminal, means for acquiring each characteristic information indicative of a gain characteristic indicating a relationship between the signal strength of the analog signal and each gain corresponding to the analog signal at the amplifier circuit, means for deriving as needed, each gain corresponding to the signal strength detected by the detecting means according to the gain characteristic represented by the characteristic information acquired by the acquiring means, and an output terminal for outputting information indicative of each gain derived from the deriving means to the amplifier circuit.

According to the invention described in the first aspect, an analog signal amplified with predetermined gain by an external amplifier circuit is inputted to an input terminal. The signal strength of the analog signal inputted to the input terminal is detected by the detecting means.

In the present invention, the acquiring means acquires characteristic information indicative of each gain characteristic indicating the relationship between the signal strength of the analog signal and each gain corresponding to the analog signal at the amplifier circuit.

In the present invention, the deriving means derives as needed, gains corresponding to the signal strengths detected by the detecting means according to the gain characteristics represented by the characteristic information acquired by the acquiring means. Information indicative of each gain derived from the deriving means is outputted to the amplifier circuit through the output terminal.

Thus, according to the invention described in the first aspect, the characteristic information indicative of each gain characteristic indicating the relationship between the signal strength of the analog signal and each gain corresponding to the analog signal at the amplifier circuit is acquired. Each gain corresponding to the detected signal strength is derived as needed according to the gain characteristic indicated by the acquired characteristic information and outputted to the amplifier circuit through the output terminal. Therefore, degradation of a reception characteristic can be suppressed because the signal strength can be controlled so as to be within a dynamic range even in such an environment that the strength of the analog signal varies due to a variation in a received electric field.

In the present invention as in the invention described in a second aspect, the characteristic information may contain rate-of-change information indicative of a rate of change in the gain with respect to a change in the signal strength, upper limit information indicative of an upper limit of each gain, lower limit information indicative of a lower limit of each gain, offset value information indicative of an offset value offset to the gain, and increase/decrease information indicative of whether the gain should be increased or decreased with an increase in the signal strength.

In the present invention as in the invention described in a third aspect, the acquiring means acquires the characteristic information in plural form every strength width of predetermined signal strengths. The deriving means may derive gains each corresponding to the signal strength detected by the detecting means according to the gain characteristics indicated by the characteristic information on the strength widths, including the signal strengths detected by the detecting means.

In the invention described in the third aspect as in the invention described in a fourth aspect, the strength widths overlap each other between the adjacent strength widths. The deriving means may be operated in such a manner that the signal strengths for switching between the characteristic information are different from one another at the characteristic information on the strength widths adjacent to one another, where the signal strength increases to shift from one strength width to the other strength width and where the signal strength decreases to shift from the other strength width to one strength width.

In the invention described in the first or second aspect as in the invention described in a fifth aspect, the analog signal is amplified by a plurality of external amplifier circuits connected in series. The acquiring means acquires the characteristic information corresponding to the amplifier circuits respectively. The deriving means is provided in plural form in association with the amplifier circuits. The plurality of deriving means derive gains corresponding to the signal strengths detected by the detecting means according to the gain characteristics represented by the characteristic information corresponding thereto. And the output terminals may output information indicative of the gains derived from the respective deriving means to the amplifier circuits respectively.

Further, as in the invention described in a sixth aspect, the present invention may further include processing means for performing predetermined signal processing on the analog signal inputted to the input terminal.

According to the present invention as described above, an excellent advantageous effect is brought about in that characteristic information indicative of each gain characteristic indicating a relationship between the signal strength of an analog signal and each gain corresponding to the analog signal at an amplifier circuit is acquired, and each gain corresponding to the detected signal strength is derived as needed according to the gain characteristic indicated by the acquired characteristic information and outputted to the amplifier circuit through an output terminal, thereby making it possible to suppress degradation of a reception characteristic because the signal strength can be controlled so as to be within a dynamic range even in such an environment that the strength of the analog signal varies due to a variation in a received electric field.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a block diagram showing a schematic configuration of a receiving section according to a first preferred embodiment;

FIG. 2 is a block diagram illustrating a functional configuration of an AGC controller according to the first preferred embodiment;

FIG. 3 is a graph showing the rate of change in gain settable by respective bits of rate-of-change information according to a preferred embodiment;

FIG. 4 is a graph illustrating offset values of gain settable by offset value information according to a preferred embodiment;

FIG. 5 is a graph showing upper and lower limits of gain respectively settable by upper limit information and lower limit information according to a preferred embodiment;

FIG. 6 is a graph illustrating a change in gain settable by increase/decrease information according to a preferred embodiment;

FIG. 7 is a graph showing a gain characteristic according to the first preferred embodiment;

FIG. 8 is a graph illustrating another example of the gain characteristic according to the first preferred embodiment;

FIG. 9 is a block diagram showing a schematic configuration of a receiving section according to second and third preferred embodiments;

FIG. 10 is a block diagram depicting a functional configuration of an AGC controller according to the second and third preferred embodiments;

FIG. 11 is a graph showing gain characteristics according to the second preferred embodiment;

FIG. 12 is a graph illustrating gain characteristics according to the third preferred embodiment at the time that the signal strength increases;

FIG. 13 is a graph depicting gain characteristics according to the second preferred embodiment at the time that the signal strength decreases;

FIG. 14 is a block diagram showing a schematic configuration of a receiving section that receives a conventional digital terrestrial broadcast; and

FIG. 15 is a graph illustrating the relationship between the signal strength of an input signal and the dynamic range of an ADC.

### DETAILED DESCRIPTION OF THE PREFERRED EMBODIMENTS

Preferred embodiments of the present invention will hereinafter be described in detail with reference to the accompanying drawings. Incidentally, a description will be made below of a case in which the present invention is applied to a receiving section of communication equipment, which receives a digital terrestrial broadcast.

### First Preferred Embodiment

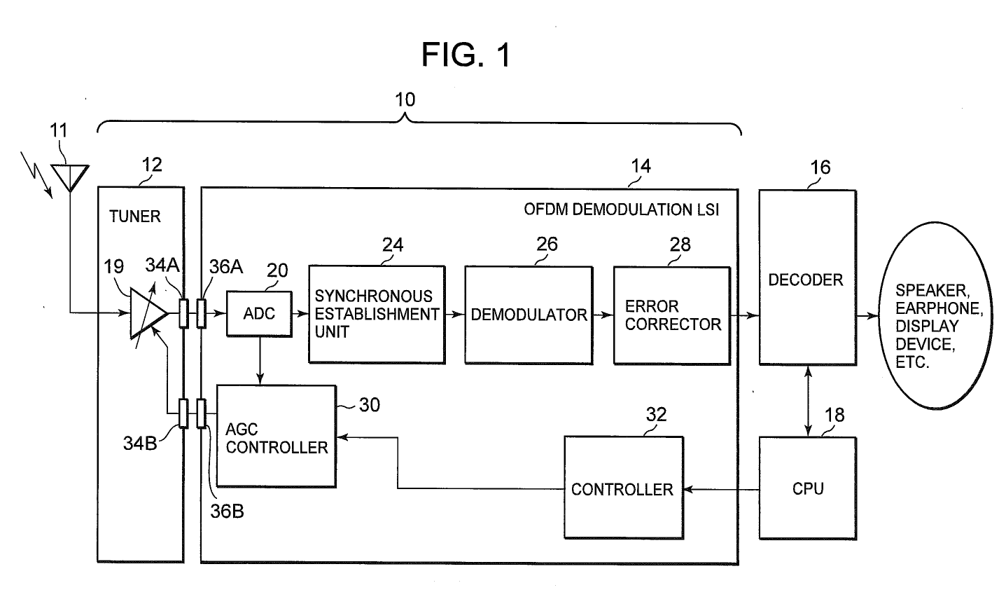

A block diagram showing a schematic configuration of a receiving section 10 according to the present embodiment, which receives a digital terrestrial broadcast, is shown in FIG. 1.

The receiving section 10 according to the present embodiment comprises a tuner LSI 12 which converts a radio wave modulated in an OFDM modulation system, which is received by an antenna 11, to an analog OFDM signal, and an OFDM demodulation LSI 14 which converts the OFDM signal to a digital signal thereby to demodulate the same. Incidentally, the OFDM signal is of a signal that comprises an effective symbol period during which one symbol period is an effective data portion, and a guard period.

The tuner LSI 12 according to the present embodiment is provided with an amplifier 19. The amplifier 19 is capable of adjusting the gain, and amplifies the OFDM signal at the gain designated by a gain control signal inputted from outside and outputs the same from a terminal 34A.

A terminal 36A of the OFDM demodulation LSI 14 is electrically connected to the terminal 34A and inputted with the analog OFDM signal outputted from the terminal 34A. A decoder 16 is connected to the OFDM demodulation LSI 14. The OFDM demodulation LSI 14 converts the inputted OFDM signal to a digital signal thereby to demodulate the same and outputs the demodulated digital OFDM signal to the decoder 16.

The decoder 16 performs decoding of the digital OFDM signal inputted from the OFDM demodulation LSI 14. The decoder 16 outputs image information contained in the decoded signal to a display device and outputs audio information contained in the signal to, for example, an audio device such as a speaker or earphone or the like.

A detailed configuration of the OFDM demodulation LSI 14 according to the present embodiment will next be explained.

As shown in FIG. 1, the OFDM demodulation LSI 14 comprises an ADC 20 which converts an analog OFDM signal inputted from the tuner LSI 12 to a digital signal, a synchronous establishment unit 24 which performs synchronization on the digital OFDM signal converted by the ADC 20 and eliminates a guard period contained in the OFDM signal thereby to extract or take out a signal (effective symbol signal) for an effective symbol period, a demodulator 26 which performs FFT (Fast Fourier Transform) on the extracted effective symbol signal to perform demodulation to a data signal corresponding to actual data, an error corrector 28 which performs error correction on data represented by the demodulated data signal, an AGC controller 30 which leads out or derives gain based on the signal strength of the inputted analog OFDM signal, and a controller 32 which controls the overall equipment.

The ADC 20 according to the present embodiment samples the received analog OFDM signal in a predetermined period or cycle and converts the same to its corresponding digital signal. Further, the ADC 20 detects a signal strength according to the voltage level of the analog OFDM signal inputted during a predetermined period, every predetermined period and outputs strength information indicative of the detected signal strength to the AGC controller 30.

The AGC controller 30 according to the present embodiment has control gain programmable in response to control information inputted from the controller 32. The AGC controller 20 leads out or derives the gain corresponding to the signal strength detected by the AGC controller 30 whenever necessary and outputs a gain control signal indicative of the derived gain through the terminal 36B. The outputted gain control signal is inputted to the amplifier 19 via a terminal 34B provided in the tuner LSI 12.

The controller 32 is connected to an external CPU 18 and inputted with characteristic information indicative of the gain characteristic of the amplifier 19 of the tuner LSI 12 from the CPU 18. The controller 32 outputs the characteristic information and number-of-times information indicative of the number of times that the gain is averaged, which are inputted from the CPU 18, to the AGC controller 30 as control information.

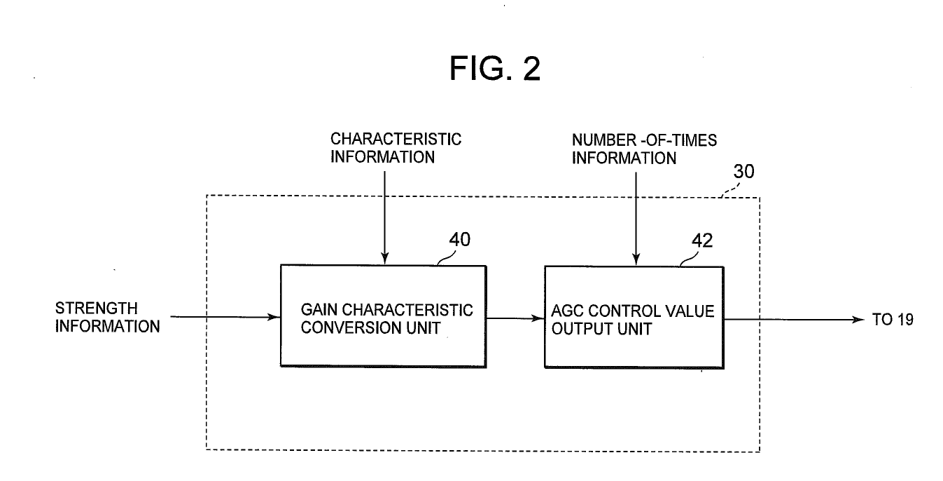

A block diagram showing a functional configuration of the AGC controller 30 according to the present invention is shown in FIG. 2.

The AGC controller 30 includes a gain characteristic conversion unit 40 and an AGC control value output unit 42. The gain characteristic conversion unit 40 according to the present embodiment is inputted with the strength information from the ADC 20 and inputted with the characteristic information from the controller 32. The AGC control value output unit 42 is inputted with the number-of-times information from the controller 32.

The gain characteristic conversion unit 40 determines or defines each gain characteristic, based on the characteristic information inputted thereto and leads out or derives the gain corresponding to the signal strength detected by the ADC 20 according to the determined gain characteristic.

The AGC control value output unit 42 determines the average gain obtained by averaging the gain derived by the gain characteristic conversion unit 40 with the number of times represented by the number-of-times information in order from new ones and outputs the average gain as a gain control signal. That is, the AGC control value output unit 42 determines the moving average of the gain derived by the gain characteristic conversion unit 40 and outputs the same therefrom.

The gain characteristic settable to the gain characteristic conversion unit 40 according to the present embodiment by the characteristic information will be explained here.

In the present embodiment, rate-of-change information indicative of the rage of change in gain, upper limit information indicative of an upper limit of each gain, lower limit information indicative of a lower limit of the gain, offset value information indicative of an offset value offset to the gain, and increase/decrease information indicative of whether the gain should be increased or decreased with an increase in the signal strength, are contained as the characteristic information.

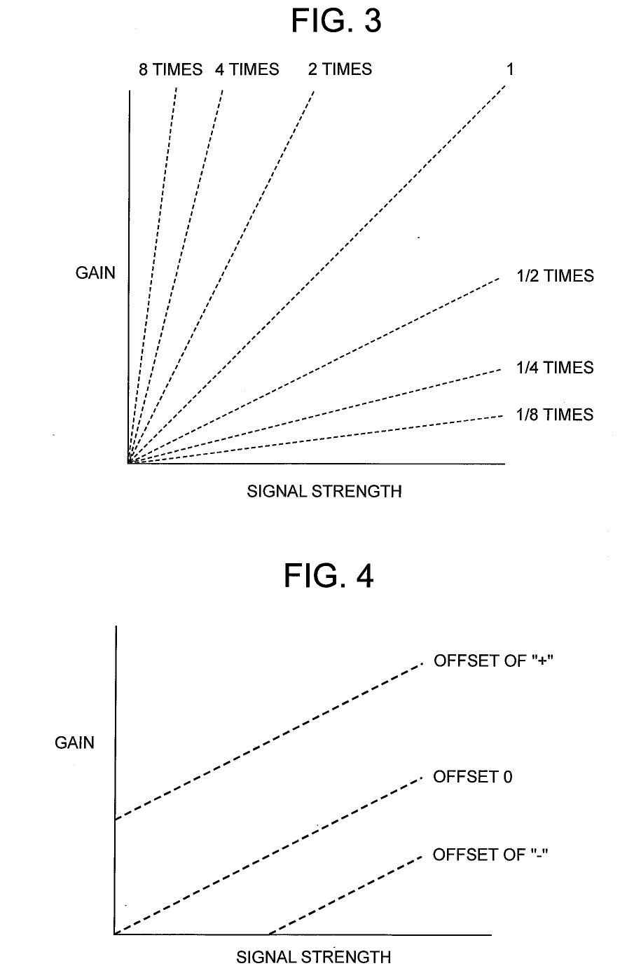

In the present embodiment, the rate-of-change information is set as information about a plurality of bits. Power multiples of 2 (for example, 8 times, 4 times, two times, double or one time, ½ times, ¼ times and ⅛ times) are caused to correspond to the respective bits as shown in FIG. 3.

The gain characteristic conversion unit 40 sets a value obtained by adding magnifying power corresponding to the position of each bit set to ‘1’ at the rate-of-change information about the plural bits, as the rate of change in gain. Thus, since ones realizable by adding power-of-2 numerals such as 2.5 times (realized by adding one left-shifted by one bit (twice or two times) and one right-shifted by one bit (0.5 times)) can be realized in the form of bit shifting and addition of inputted values, this is very efficient in terms of a circuit area.

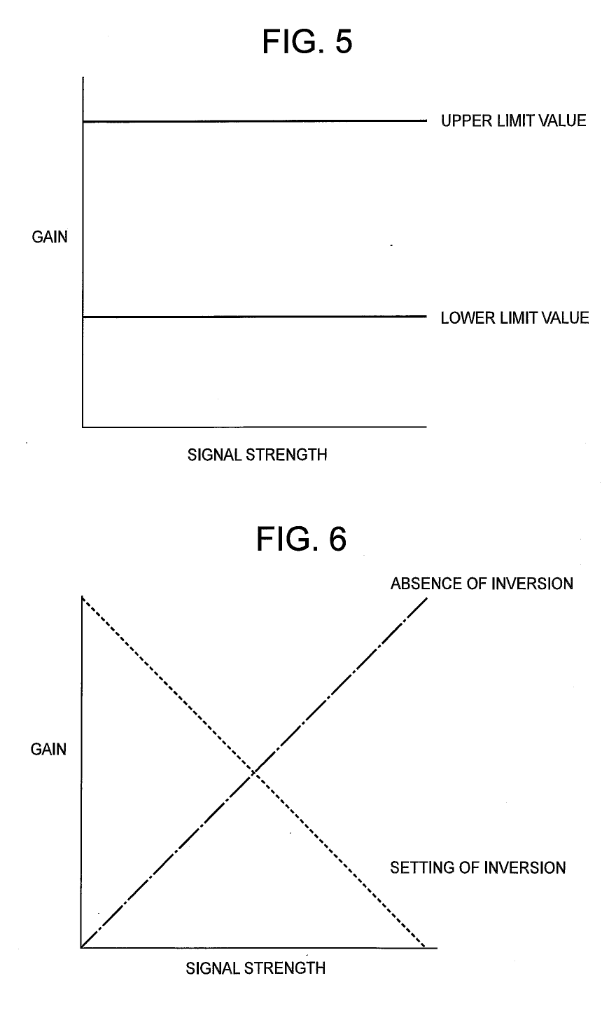

The gain characteristic conversion unit 40 changes the offset value of the gain according to the offset value information as shown in FIG. 4, changes the upper limit of the gain and the lower limit thereof according to the upper limit information and the lower limit information respectively as shown in FIG. 5, and changes the gain to determine whether the gain should be increased or decreased with the increase in signal strength.

A basic operation of the receiving section 10 according to the present embodiment will next be explained.

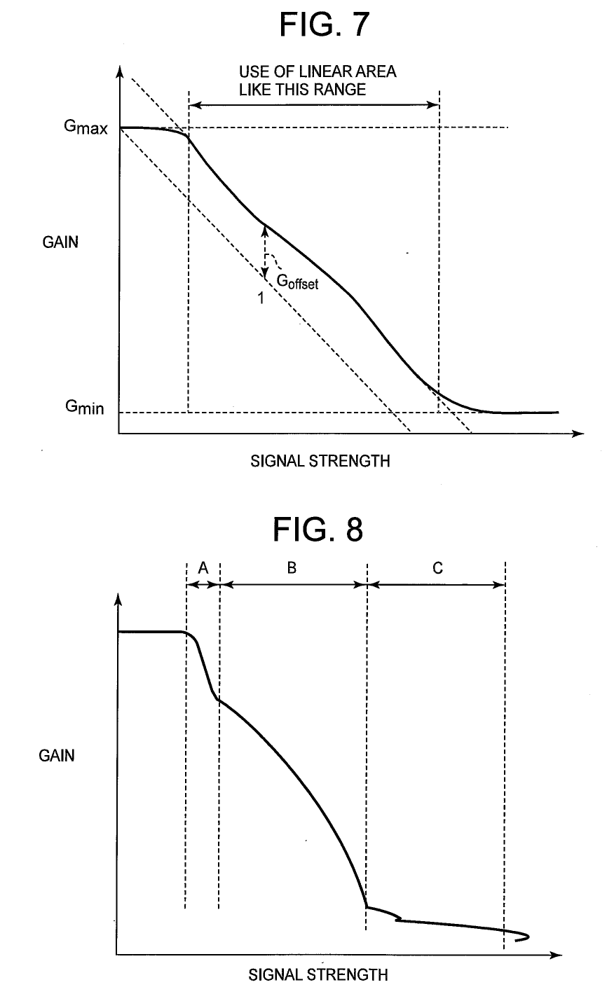

A gain characteristic optimum to the amplifier 19 of the tuner LSI 12 mounted as the receiving section 10 is measured in advance. For example, when the gain characteristic of the amplifier 19 corresponding to the signal strength optimum to maintain the signal strength of the OFDM signal inputted to the OFDM demodulation LSI 14 within an input dynamic range is of such a gain characteristic as shown in FIG. 7, characteristic information set as such a gain characteristic as to reduce the gain with the increase in signal strength assuming that the rate of change in gain is taken as double, the upper limit is taken as gₘₐₓ, the lower limit is taken as Gₘᵢₙ and the offset value is taken G_{OFFSET} is inputted from the CPU 18 to the controller 32.

The controller 32 outputs the inputted characteristic information and the number-of-times information indicative of the number of times that the gain is averaged, to the AGC controller 30 as control information.

Thus, the gain characteristic conversion unit 40 defines the gain characteristic in the approximate form of such a gain characteristic as shown in FIG. 7.

The tuner LSI 12 converts the radio wave received by the antenna 11 to its corresponding analog OFDM signal and amplifies the same through the amplifier 19, and outputs the amplified OFDM signal to the OFDM demodulation LSI 14 through the terminal 34A.

The OFDM demodulation LSI 14 converts the OFDM signal inputted from the terminal 36A to a digital signal at the ADC 20 and demodulates the same via the synchronous establishment unit 24 and the demodulator 26. Further, the OFDM demodulation LSI 14 detects the signal strength of the analog OFDM signal at the ADC 20 and outputs strength information indicative of the detected signal strength to the gain characteristic conversion unit 40.

The gain characteristic conversion unit 40 derives each gain corresponding to the signal strength through the use of the gain characteristic represented by the characteristic information whenever necessary and outputs the same to the AGC control value output unit 42.

The AGC control value output unit 42 determines the average gain obtained by averaging the gain derived by the gain characteristic conversion unit 40 by the number of times represented by the number-of-times information in order from new ones and outputs the average gain from the terminal 36B as a gain control signal.

The gain of the amplifier 19 is changed according to the gain control signal, so that the signal strength of the analog OFDM signal is changed.

According to the present embodiment as described above, the characteristic information is inputted from the CPU 18 to the OFDM demodulation LSI 14 thereby to make it possible to cause the OFDM demodulation LSI 14 to correspond or adapt to the gain characteristic of the amplifier 19 of the tuner LSI 12. It is thus possible to provide the optimum gain characteristic even in the case of the tuner LSI 12 free of its adaptation at the design stage. It is also possible to adapt to such dynamic environments that a received electric field always varies as typified by fading and a multipath.

According to the present embodiment, it is not necessary to provide a plurality of circuits for adapting to a plurality of gain characteristics in the OFDM demodulation LSI 14. The present embodiment is thus efficient in terms of the area.

Further, according to the present embodiment, even when the characteristic of the tuner LSI 12 is changed in midstream due to a change in specifications or the like, adaptation to it is made possible by a correction to the characteristic information, thus making it possible to enjoy a large merit.

Incidentally, although the present embodiment has explained where the rate-of-change information, upper limit information, lower limit information, offset value information and increase/decrease information are contained one by one as the characteristic information, characteristic information are inputted from the CPUT 18 every strength width (strength widths A, B and C in FIG. 8) of predetermined signal strengths as shown in FIG. 8, gain characteristics are determined based on the inputted respective characteristic information at the ADC controller 30, and gain corresponding to the signal strengths may be led out or derived according to the gain characteristics represented by the characteristic information on the strength widths, including the signal strengths detected by the ADC 20.

Thus, adaptation to a gain characteristic having a plurality of linear areas can be realized in addition to adaptation to the simple linear gain characteristic. Control on such a variable or programmable gain amplifier that it can be realized by a plurality of linear curves is also enabled as well as a programmable gain amplifier excellent in characteristic, which realizes simple linear gain control.

Even though the amplifier 19 has a simple linear gain characteristic, the inclination normally changes due to its saturation in the neighborhood of an analog saturated region. Since, however, such a neighborhood of saturated region can be covered with an approximate line to some degree, an advantageous effect that the dynamic range is expanded is brought about.

### Second Preferred Embodiment

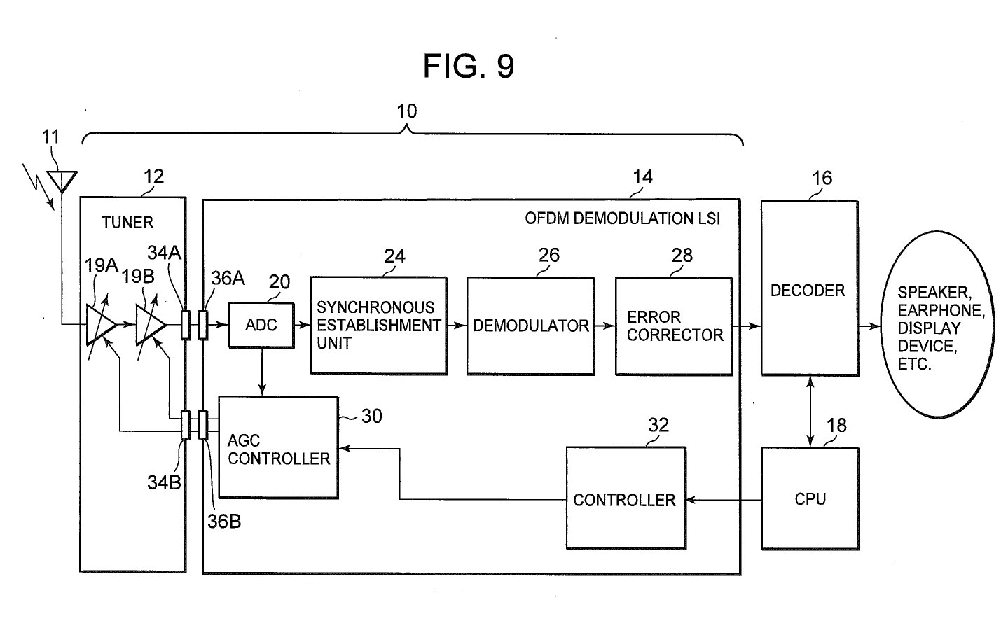

A schematic configuration of a receiving section 10 according to a second embodiment is shown in FIG. 9. Incidentally, the same reference numerals are respectively attached to the same constituent elements as those shown in FIG. 1 in the same figure, and their explanations will be omitted.

Normally, a tuner LSI 12 is difficult to cove a dynamic range over all gains with one amplifier 19.

Therefore, the tuner LSI 12 according to the present embodiment is configured in such a manner that a plurality of amplifiers 19 (two amplifiers 19A and 19B in the present embodiment) are provided with being connected in series and an analog OFDM signal is amplified by the respective amplifiers 19.

An AGC controller 30 according to the present embodiment controls the respective gains of the amplifiers 19.

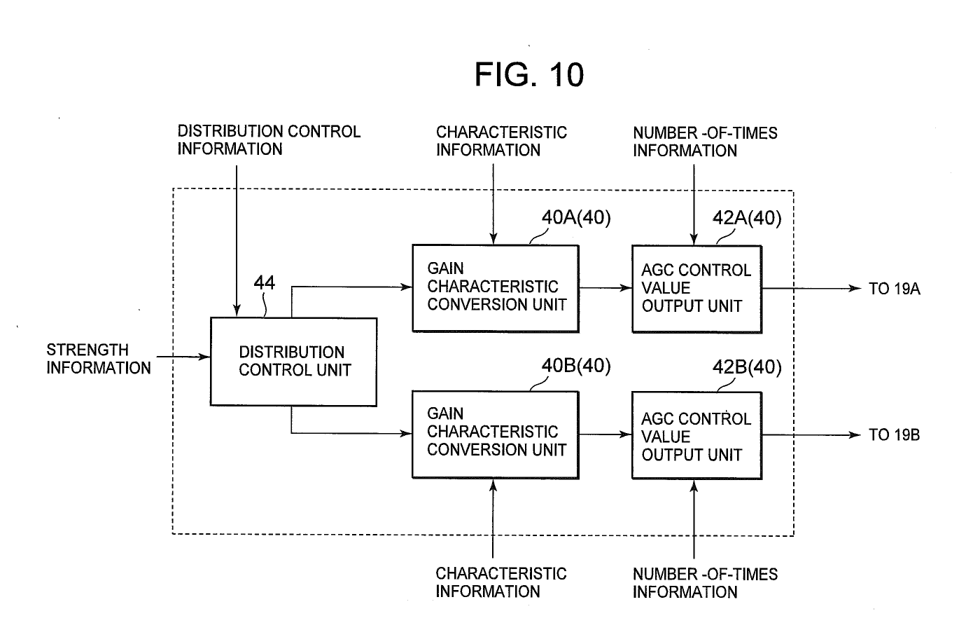

A block diagram showing a functional configuration of the AGC controller 30 according to the present embodiment is shown in FIG. 10.

The AGC controller 30 is provided with two of a gain characteristic conversion unit 40 and an AGC control value output unit 42 in association with the two amplifiers 19A and 19B. A distribution control unit 44 is further provided in the AGC controller 30. Of the two gain characteristic conversion unit 40 and AGC control value output unit 42, ones corresponding to the amplifier 19A are taken as a gain characteristic conversion unit 40A and an AGC control value output unit 42A, and ones corresponding to the amplifier 19B are taken as a gain characteristic conversion unit 40B and an AGC control value output unit 42B.

A controller 32 is inputted with characteristic information indicative of the gain characteristics of the amplifiers 19A and 19B and distribution information to be described later from a CPU 18.

The controller 32 outputs the characteristic information of the amplifier 19A to the gain characteristic conversion unit 40A and outputs the characteristic information of the amplifier 19B to the gain characteristic conversion unit 40B. The controller 32 also outputs number-of-times information indicative of the number of times that the gain is averaged, to the AGC control value output units 42A and 42B. Further, the controller 32 outputs the distribution information to the distribution control unit 44.

The distribution control unit 44 according to the present embodiment is inputted with strength information indicative of the signal strength of an OFDM signal from an ADC 20 and distributes signal strengths to the gain characteristic conversion unit 40A and the gain characteristic conversion unit 40B, respectively, based on the distribution information inputted from the controller 32.

A basic operation of the receiving section 10 according to the present embodiment will next be explained.

Since the frequencies and characteristics handled in the respective amplifiers 19 differ from one another although amplification is done by the amplifiers 19 in the tuner LSI 12, a difference occurs even between the respective gain characteristics thereof.

Thus, the gain characteristics optimum to the respective amplifiers 19 of the tuner LSI 12 are measured in advance. Then, the characteristic information indicative of the gain characteristics of the respective amplifiers 19, and the distribution information indicative of distribution of the signal strengths corresponding to the respective amplifiers 19 are inputted from the CPUT 18 to the controller 32.

The controller 32 outputs the inputted respective characteristic information, number-of-times information and distribution information to the gain characteristic conversion units 40A and 40B, AGC control value output units 42A and 42B and distribution control unit 44 respectively.

Thus, the gain characteristics of the gain characteristic conversion units 40A and 40B are defined.

The distribution control unit 44 distributes the signal strength detected at the ADC 20 to the gain characteristic conversion units 40A and 40B, respectively, based on the distribution information.

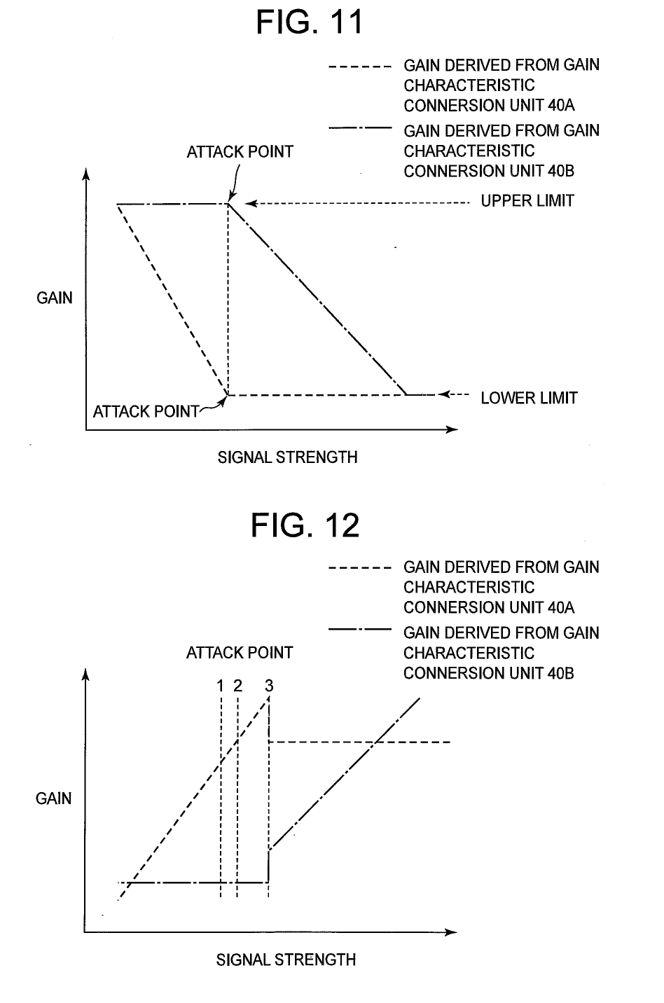

When the amplifier 19A can cover 30% of the total and the amplifier 19B can cover 70% of the total, for example, the distribution information is inputted in such a manner that the distribution is done as shown in FIG. 11, for example.

The gain characteristic conversion units 40A and 40B derive gains corresponding to the signal strengths according to the gain characteristics indicated by the characteristic information respectively whenever necessary. The AGC control value output units 42A and 42B respectively determine the average gains obtained by averaging the gains derived from the gain characteristic conversion units 40A and 40B with the number of times indicated by the number-of-times information in order from new ones and output the average gains as gain control signals.

Thus, in such a case as shown in FIG. 11 by way of example, both the gains derived from the gain characteristic conversion units 40A and 40B reach the maximum gain (upper limit) when the signal strength is extremely low. The AGC controller 30 is operated in such a manner that when the input level rises therefrom, the gain derived from the gain characteristic conversion unit 40A is lowered and the signal strength is maintained at a targeted level. The gain derived from the gain characteristic conversion unit 40B is lowered from the point where the gain derived from the gain characteristic conversion unit 40A is brought to a lower limit.

When the signal strength is extremely large in reverse, both gains derived from the gain characteristic conversion units 40A and 40B are respectively brought to the minimum gain (lower limit). The AGC controller 30 is operated in such a manner that when the signal strength is lowered from the lower limit, the gain derived from the gain characteristic conversion unit 40B rises and the signal strength is maintained at a targeted level. Then, the gain derived from the gain characteristic conversion unit 40A is raised from the point where the gain derived from the gain characteristic conversion unit 40A is brought to the upper limit. A point where the gain characteristics of the gain characteristic conversion unit 40A and the gain characteristic conversion unit 40B are switched over, is called an attack point.

According to the present embodiment as described above, the OFDM demodulation LSI 14 can make use of merits that the respective amplifiers 19 have. With the implementation of the above ideal distribution, the gain characteristic conversion units are respectively capable of leading out a satisfactory result reduced in distortion. A system in which a plurality of amplifiers 19 different in gain characteristic are utilized in combination, can cover all gains required.

At this time, gain amounts coverable with the plural gains are set in the form of attack points, and the amount of distribution is changed to the optimum value, whereby the merits that the respective amplifiers 19 have can be utilized effectively. With the implementation of this ideal distribution, the AGC controller 30 can lead out a satisfactory result reduced in distortion.

### Third Preferred Embodiment

Since a receiving section 10 and an AGC controller 30 according to a third embodiment are identical in configuration to those according to the second embodiment (refer to FIGS. 9 and 10), their explanations will be omitted herein.

A distribution control unit 44 according to the present embodiment is inputted with information indicative of a plurality of attack points from a controller 32 as distribution information. The distribution control unit 44 distributes signal strengths to gain characteristic conversion units 40A and 40B based on the distribution information respectively. Incidentally, the present embodiment will explain a case in which three attack points are inputted as distribution information assuming that a gain characteristic switching point at the time that the signal strength shifts or moves from large to small is taken as an attack point 1, the connecting positions of the original two gain characteristics are taken as an attack point 2, and a gain characteristic switching point at the time that the signal strength moves from small to large is taken as an attack point 3 as shown in FIG. 12.

A basic operation of the receiving section 10 according to the present embodiment will next be explained.

When the signal strength is varying from small to large as shown in FIG. 12, the distribution control unit 44 is operated without switching up to the attack point 3 and switched over only beyond the attack point 3.

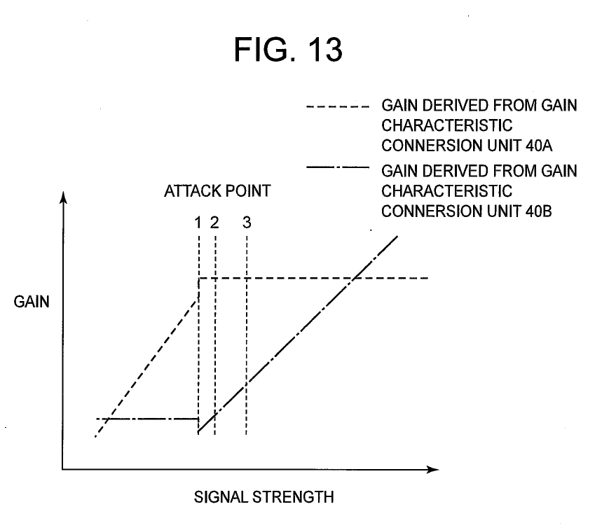

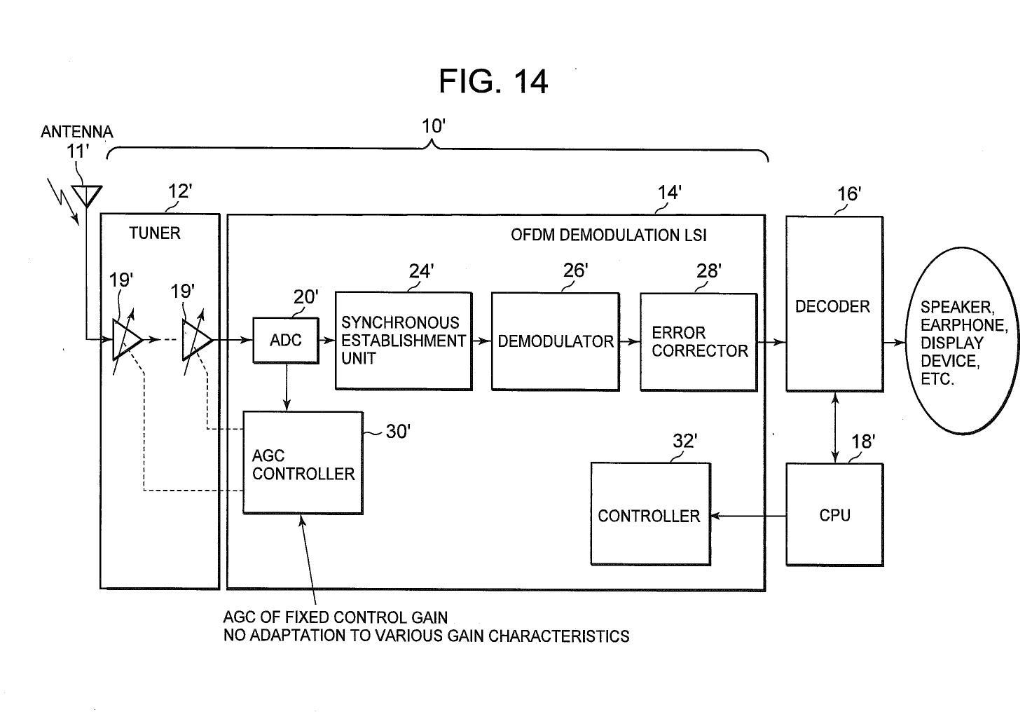

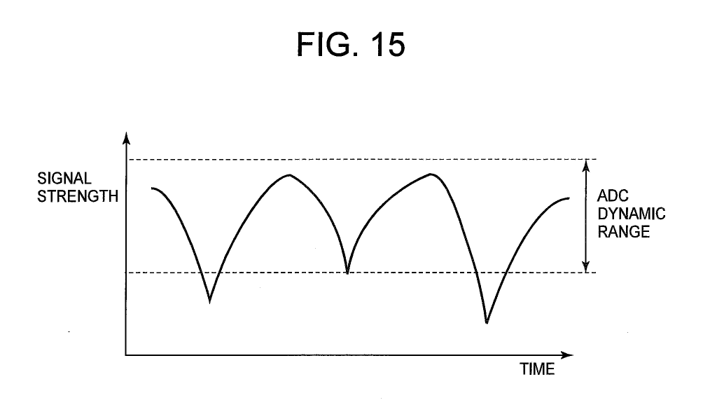

On the other hand, when the signal strength is varying from large to small as shown in FIG. 13, the distribution control unit 44 is operated without switching up to the attack point 1 and switched over only beyond the attack point 1.

According to the present embodiment as described above, asymmetric hysteresis switching can be realized where the signal strength increases and decreases. Even though reception power varies in the neighborhood of a region that exceeds the attack point 3, for example, the distribution control unit is brought to a stable operation without being changed over because of the switching attack point 1 at the time that the reception power is shifted from large to small.

Incidentally, although each of the preferred embodiments has explained where the characteristic information is acquired from the CPU 18 by the controller 32, the present invention is not limited to it. For example, the characteristic information may directly be inputted from the CPU 18 to the AGC controller 30. In this case, an input terminal to which the characteristic information is inputted, is used as acquiring means.

Although each of the preferred embodiments has explained the case in which the characteristic information is acquired from the external CPU 18, the present invention is not limited to it. For example, non-volatile storing means such as a ROM is provided and the characteristic information is stored in the storing means. In this state, the characteristic information may be acquired by being read from the storing means. In this case, means for reading the characteristic information becomes acquiring means.

Although each of the respective preferred embodiments has explained the case in which the present invention is applied to the receiving section 10 of the communication equipment, which receives the digital terrestrial broadcast, the present invention is not limited to it.

In other respects, the configuration (refer to FIGS. 1 and 9) of the receiving section 10 described in each of the preferred embodiments and the configuration (refer to FIGS. 2 and 10) of the AGC controller 30 are cited by way of example. It is needless to say that changes can suitably be done within the scope not departing from the gist of the present invention.

What is claimed is:

1. A gain control device comprising:
an input terminal inputted with an analog signal amplified with predetermined gain by an external amplifier circuit;
means for detecting a signal strength of the analog signal inputted to the input terminal;
means for acquiring each characteristic information indicative of a gain characteristic indicating a relationship between the signal strength of the analog signal and each gain corresponding to the analog signal at the amplifier circuit;
means for deriving as needed, each gain corresponding to the signal strength detected by the detecting means according to the gain characteristic represented by the characteristic information acquired by the acquiring means; and
an output terminal for outputting information indicative of each gain derived from the deriving means to the amplifier circuit.

2. The gain control device according to claim 1, wherein the characteristic information contains rate-of-change information indicative of a rate of change in the gain with respect to a change in the signal strength, upper limit information indicative of an upper limit of each gain, lower limit information indicative of a lower limit of each gain, offset value information indicative of an offset value offset to the gain, and increase/decrease information indicative of whether the gain is increased or decreased with an increase in the signal strength.

3. The gain control device according to claim 1, wherein the acquiring means acquires the characteristic information in plural form every strength width of predetermined signal strengths, and
wherein the deriving means derives gains each corresponding to the signal strength detected by the detecting means according to the gain characteristics indicated by the characteristic information on the strength widths, including the signal strengths detected by the detecting means.

4. The gain control device according to claim 3, wherein the strength widths overlap each other between the adjacent strength widths, and
wherein the deriving means is operated in such a manner that the signal strengths for switching between the characteristic information differ at the characteristic information on the strength widths adjacent to one another where the signal strength increases to shift from one strength width to the other strength width and where the signal strength decreases to shift from the other strength width to one strength width.

5. The gain control device according to claim 1, wherein the analog signal is amplified by a plurality of external amplifier circuits connected in series,
wherein the acquiring means acquires the characteristic information corresponding to the amplifier circuits respectively,
wherein the deriving means is provided in plural form in association with the amplifier circuits, and the plurality of deriving means derive gains corresponding to the signal strengths detected by the detecting means according to the gain characteristics represented by the characteristic information corresponding thereto, and
wherein the output terminal outputs information indicative of each of the gains derived from the respective deriving means to each of the amplifier circuits.

6. The gain control device according to claim 1, further including processing means for performing predetermined signal processing on the analog signal inputted to the input terminal.
